(19) United States
(12) Patent Application Publication
(10) Pub. No.: US 2026/0214966 A1
(43) Pub. Date: Jul. 23, 2026

(54) SEMICONDUCTOR STRUCTURE AND METHOD OF FORMING THEREOF

(71) Applicant: TAIWAN SEMICONDUCTOR MANUFACTURING COMPANY, LTD., Hsinchu (TW)

(72) Inventors: Shih-Jung HO, Hsinchu City (TW); Olivia Pei-Hua LEE, Hsinchu County (TW); Hsin WANG, New Taipei City (TW); Hao-Chin HUANG, Kaohsiung City (TW); Wei-Yip LOH, Hsinchu City (TW); Po-Chin CHANG, Taichung City (TW); Chia-Hung CHU, Taipei City (TW); Sung-Li WANG, Hsinchu County (TW); Ku-Feng YANG, Hsinchu County (TW); Pinyen LIN, Rochester, NY (US); Szuya LIAO, Hsinchu County (TW)

(73) Assignee: TAIWAN SEMICONDUCTOR MANUFACTURING COMPANY, LTD., Hsinchu (TW)

(21) Appl. No.: 19/034,128

(22) Filed: Jan. 22, 2025

(51) Int. Cl. H10D 84/01; H10D 84/85

(52) U.S. Cl. CPC H10D 84/0186; H10D 84/017; H10D 84/851; H10D 84/856

(57) ABSTRACT

A method includes a number of operations. A bottom transistor is formed over a substrate. A top transistor is formed over the top transistor. An opening is formed and extends through a source/drain region of the top transistor to a source/drain region of the bottom transistor, wherein the opening further extends through an interlayer dielectric (ILD) layer between the source/drain regions of the top and bottom transistors. A metal-containing material is formed over the source/drain regions of the top and bottom transistors to form silicide layers over the source/drain regions of the top and bottom transistors, wherein recesses in sidewalls of the ILD layer are filled with the metal-containing material. After forming the metal-containing material, a metal gap-fill material is formed in the opening.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional view of an example CFET structure in accordance with some embodiments of the present disclosure;

FIG. 2 illustrates a three-dimensional view of intermediate stages in the formation of CFETs in accordance with some embodiment; and

FIGS. 3 through 9C illustrate schematic cross-sectional views of intermediate stages in the formation of CFETs in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to a semiconductor device of a Complementary Field-Effect Transistor (CFET) structure. While Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFETs.

Various embodiments of the present disclosure relate to the semiconductor structures of Complementary Field Effect Transistor (CFET) devices and the methods for forming the semiconductor structures. In some embodiments, a Metal Over Diffusion Local Interconnect (MDLI) is surrounded by a liner insulating layer within the semiconductor structure. This MDLI connects an upper source/drain region with a corresponding lower source/drain region, where the upper region overlaps the lower region. In some embodiments, a scheme involving the initial formation of the liner insulating layer is used in the MDLI growth process. During this process, the lower interlayer dielectric (ILD) layer above the upper source/drain region may be etched, potentially resulting in a bowing profile. The MDLI formed along the bowing profile of the upper source/drain region may include voids within, and it increases the resistance of the MDLI and results in reliability issues. In one or more embodiments of the present disclosure, a metal-containing material for forming silicide layer can fill with the bowing profile of the lower ILD layer. The MDLI formed on the lower ILD layer with refilled bowing profile may be cost-effective metal gap-filling without voids, thus achieving low resistance and improving the reliability of the semiconductor device.

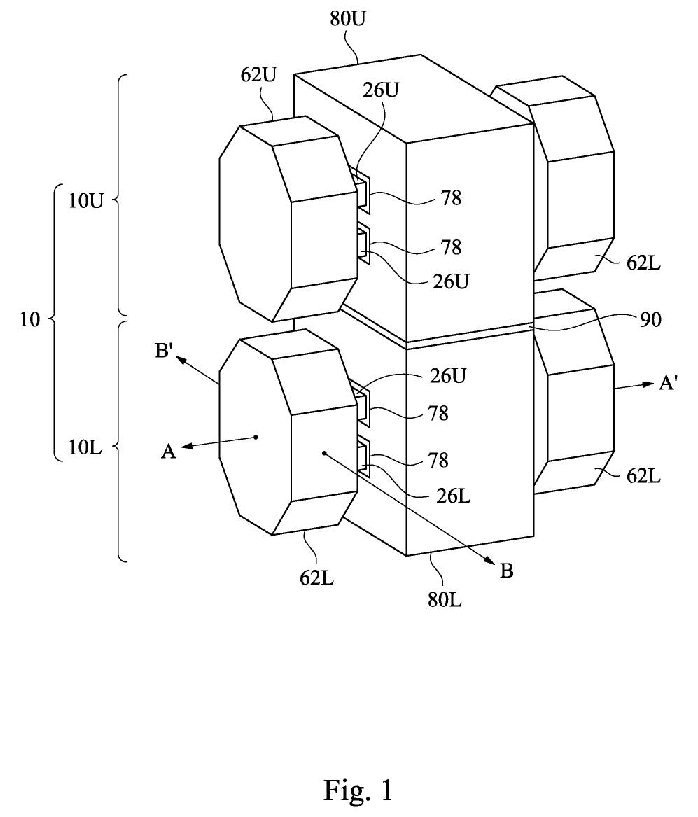

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L and the upper semiconductor nanostructures 26U are for the upper nanostructure-FET 10U.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80. The gate dielectrics 78 and the respective gate electrodes 80L and 80U are collectively referred to as gate stacks 90.

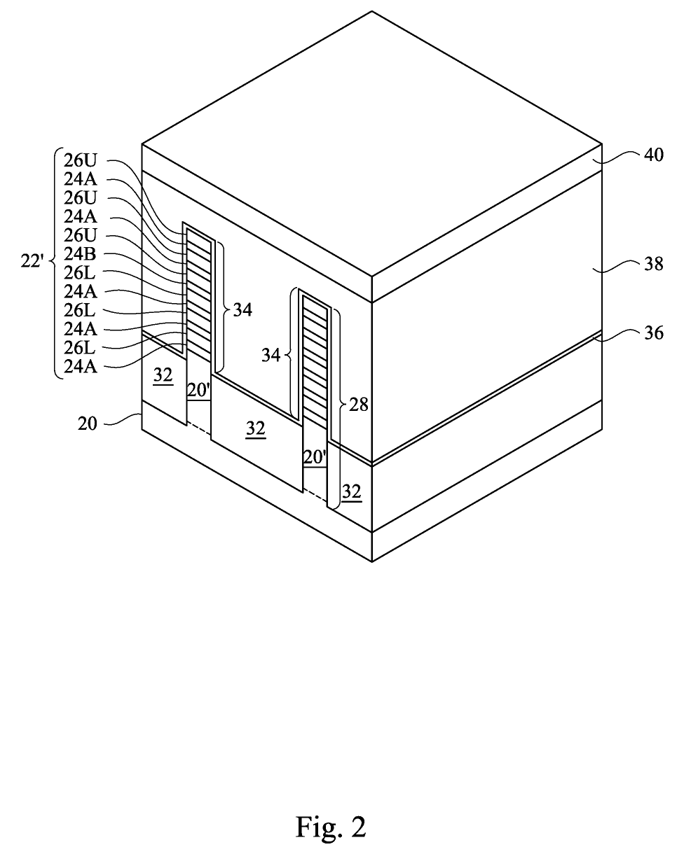

Reference is made to FIG. 2. FIG. 2 illustrates a three-dimensional view of intermediate stages in the formation of CFETs in accordance with some embodiments. FIG. 2 illustrates forming a plurality of nanostructures 22 including nanostructures 26U, 26M, and 26L over a plurality of semiconductor strips 20’ of the substrate 20.

In FIG. 2, a substrate 20 is provided. The substrate 20 may be a semiconductor substrate, such as a bulk semiconductor, a semiconductor-on-insulator (SOI) substrate, or the like, which may be doped (e.g., with a p-type or an n-type dopant) or undoped. The substrate 20 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 20 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 22’ is formed over the substrate 20. The multi-layer stack 22’ includes alternating dummy layers 24 (including first dummy layers 24A and a second dummy layer 24B) and semiconductor layers 26 (including lower semiconductor layers 26L and upper semiconductor layers 26U). The lower semiconductor layers 26L and a subset of the first dummy layers 24A are disposed below the second dummy layer 24B. The upper semiconductor layers 26U and another subset of the first dummy layers 24A are disposed above the second dummy layer 24B. As subsequently described in greater detail, the dummy layers 24 will be removed and the semiconductor layers 26 will be patterned to form channel regions of CFETs. Specifically, the lower semiconductor layers 26L will be patterned to form channel regions of the lower nanostructure-FETs of the CFETs, and the upper semiconductor layers 26U will be patterned to form channel regions of the upper nanostructure-FETs of the CFETs.

The multi-layer stack 22’ is illustrated as including six of the dummy layers 24 and six of the semiconductor layers 26. It should be appreciated that the multi-layer stack 22’ may include any number of the dummy layers 24 and the semiconductor layers 26. Each layer of the multi-layer stack 22’ may be grown by a process such as vapor phase epitaxy (VPE) or molecular beam epitaxy (MBE), deposited by a process such as chemical vapor deposition (CVD) or atomic layer deposition (ALD), or the like.

The first dummy layers 24A are formed of a first semiconductor material, and the second dummy layer 24B is formed of a second semiconductor material. The first and second semiconductor materials may be selected from the candidate semiconductor materials of the substrate 20. The semiconductor materials of the first dummy layers 24A and the second dummy layer 24B will be subsequently described in greater detail. The first and second semiconductor materials have a high etching selectivity to one another. As such, the material of the second dummy layer 24B may be removed at a faster rate than the material of the first dummy layers 24A in subsequent processing.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. In some embodiments, the semiconductor layers 26 are formed of a group IV-V material or a group III-V material. The lower semiconductor layers 26L and the upper semiconductor layers 26U may be formed of the same semiconductor material, or may be formed of different semiconductor materials. In some embodiments, the lower semiconductor layers 26L and the upper semiconductor layers 26U are both formed of a semiconductor material suitable for p-type devices and n-type devices, such as silicon. In some embodiments, the lower semiconductor layers 26L are formed of a semiconductor material suitable for p-type devices, such as germanium or silicon-germanium, and the upper semiconductor layers 26U are formed of a semiconductor material suitable for n-type devices, such as silicon or carbon-doped silicon. The semiconductor material(s) of the semiconductor layers 26 will be subsequently described in greater detail. The semiconductor material(s) of the semiconductor layers 26 have a high etching selectivity to the semiconductor materials of the dummy layers 24. As such, the materials of the dummy layers 24 may be removed at a faster rate than the material of the semiconductor layers 26 in subsequent processing.

Some layers of the multi-layer stack 22’ may be thicker than other layers of the multi-layer stack 22’. The thickness of the second dummy layer 24B may be different (e.g., greater or less) than the thickness of each of the first dummy layers 24A. In some embodiments, the second dummy layer 24B has a large thickness, such as a greater thickness than each of the first dummy layers 24A. Forming the second dummy layer 24B to a large thickness allows the second dummy layer 24B to be more easily removed in subsequent processing. Additionally, the thickness of each of the semiconductor layers 26 may be different (e.g., greater or less) than the thickness(es) of each of the first dummy layers 24A and/or the second dummy layer 24B. In some embodiments, each of the semiconductor layers 26 may be thicker than each of the dummy layers 24.

In some embodiments, the first dummy layers 24A are formed of silicon- germanium with a first germanium atomic percentage, the second dummy layer 24B is formed of silicon-germanium with a second germanium atomic percentage that is higher than the first germanium atomic percentage. The difference between the second germanium atomic percentage and the first germanium atomic percentage may be higher than about 30 percent, and may be in the range between about 30 percent and about 70 percent. The higher germanium atomic percentage allows the second dummy layer 24B to be etched at a faster rate than the first dummy layers 24A, and allows the second dummy layer 24B to be completely removed during a subsequent etching process, as discussed hereinafter.

After the multi-layer stack 22’ is formed over the substrate 20, the substrate 20 and the multi-layer stack 22’ are patterned. In FIG. 2, fins 20’ are formed in the substrate 20 and nanostructures 24, 26 (including first dummy nanostructures 24A, second dummy nanostructures 24B, lower semiconductor nanostructures 26L, middle semiconductor nanostructures 26M, and upper semiconductor nanostructures 26U) are formed in the multi-layer stack 22’. In some embodiments, the nanostructures 24, 26 and the fins 20’ may be formed in the multi-layer stack 22’ and the substrate 20, respectively, by etching trenches in the multi-layer stack 22’ and the substrate 20. The etching may be any acceptable etch process, such as a reactive ion etch (RIE), neutral beam etch (NBE), the like, or a combination thereof. The etching may be anisotropic. Forming the nanostructures 24, 26 by etching the multi-layer stack 22’ may define the first dummy nanostructures 24A from the first dummy layers 24A, the second dummy nanostructures 24B from the second dummy layer 24B, the lower semiconductor nanostructures 26L from some of the lower semiconductor layers 26L, the upper semiconductor nanostructures 26U from some of the upper semiconductor layers 26U, and the middle semiconductor nanostructures 26M from some of the lower semiconductor layers 26L and some of the upper semiconductor layers 26U. The first dummy nanostructures 24A and the second dummy nanostructures 24B may further be collectively referred to as the dummy nanostructures 24. The lower semiconductor nanostructures 26L and the upper semiconductor nanostructures 26U may further be collectively referred to as the semiconductor nanostructures 26.

As subsequently described in greater detail, the dummy nanostructures 24 will be removed to form channel regions of CFETs. Specifically, the lower semiconductor nanostructures 26L will act as channel regions for lower nanostructure-FETs of the CFETs. Additionally, the upper semiconductor nanostructures 26U will act as channel regions for upper nanostructure-FETs of the CFETs.

The middle semiconductor nanostructures 26M are the semiconductor nanostructures 26 that are directly above/below (e.g., in contact with) the second dummy nanostructures 24B. Depending on the heights of subsequently formed source/drain regions, the middle semiconductor nanostructures 26M may or may not adjoin any source/drain regions and may or may not act as functional channel regions for the CFETs. The second dummy nanostructures 24B will be subsequently replaced with isolation structures. The isolation structures and the middle semiconductor nanostructures 26M may define boundaries of the lower nanostructure-FETs and the upper nanostructure-FETs.

The fins 20’ and the nanostructures 24, 26 may be patterned by any suitable method. For example, the fins 20’ and the nanostructures 24, 26 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 20’ and the nanostructures 24, 26. In some embodiments, a mask (or other layer) may remain on the nanostructures 24, 26.

Although each of the fins 20’ and the nanostructures 24, 26 is illustrated as having a constant width throughout, in other embodiments, the fins 20’ and/or the nanostructures 24, 26 may have tapered sidewalls such that a width of each of the fins 20’ and/or the nanostructures 24, 26 continuously increases in a direction towards the substrate 20. In such embodiments, each of the nanostructures 24, 26 may have a different width and be trapezoidal in cross-section view.

In FIG. 2, isolation regions 32 are formed adjacent to the fins 20’. The isolation regions 32 may be formed by depositing an insulating material over the substrate 20, the fins 20’, and nanostructures 24, 26, and between adjacent fins 20’. The insulating material may be an oxide, such as silicon oxide, a nitride, or the like, or a combination thereof, and may be formed by high-density plasma chemical vapor deposition (HDP-CVD), flowable chemical vapor deposition (FCVD), or the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 24, 26. Although the insulating material is illustrated as a single layer, some embodiments may utilize multiple layers. For example, in some embodiments a liner (not separately illustrated) may first be formed along a surface of the substrate 20, the fins 20’, and the nanostructures 24, 26. Thereafter, a fill material, such as one of the previously described insulating materials may be formed over the liner.

A removal process is then applied to the insulating material to remove excess insulating material over the nanostructures 24, 26. In some embodiments, a planarization process such as a chemical mechanical polish (CMP), an etch-back process, combinations thereof, or the like may be utilized. The planarization process exposes the nanostructures 24, 26 such that top surfaces of the nanostructures 24, 26 and the insulating material are level after the planarization process is complete.

The insulating material is then recessed to form the isolation regions 32. The insulating material is recessed such that upper portions of the fins 20’ protrude from between neighboring isolation regions 32. Further, the top surfaces of the isolation regions 32 may have a flat surface as illustrated, a convex surface, a concave surface (such as dishing), or a combination thereof. The top surfaces of the isolation regions 32 may be formed flat, convex, and/or concave by an appropriate etch. The isolation regions 32 may be recessed using an etching process, such as one that is selective to the insulating material (e.g., selectively etches the insulating material at a faster rate than the materials of the fins 20’ and the nanostructures 24, 26). For example, an oxide removal using, for example, dilute hydrofluoric (dHF) acid may be used.

In FIG. 2, a dummy dielectric layer 36 is formed on the fins 20’ and/or the nanostructures 24, 26. The dummy dielectric layer 36 may be, for example, silicon oxide, silicon nitride, a combination thereof, or the like, and may be deposited or thermally grown according to acceptable techniques. A dummy gate layer 38 is formed over the dummy dielectric layer 36, and a mask layer 40 is formed over the dummy gate layer 38. The dummy gate layer 38 may be deposited over the dummy dielectric layer 36 and then planarized, such as by a CMP. The mask layer 40 may be deposited over the dummy gate layer 38. The dummy gate layer 38 may be a conductive or non-conductive material and may be selected from a group including amorphous silicon, polycrystalline-silicon (polysilicon), poly-crystalline silicon-germanium (poly-SiGe), or the like. The dummy gate layer 38 may be deposited by physical vapor deposition (PVD), CVD, sputter deposition, or other techniques for depositing the selected material. The dummy gate layer 38 may be formed of other materials that have a high etching selectivity to insulating materials. The mask layer 40 may include, for example, silicon nitride, silicon oxynitride, or the like. In the illustrated embodiment, the dummy dielectric layer 36 covers the isolation regions 32, such that the dummy dielectric layer 36 extends between the dummy gate layer 38 and the isolation regions 32. In another embodiment, the dummy dielectric layer 36 covers only the fins 20’ and/or the nanostructures 24, 26.

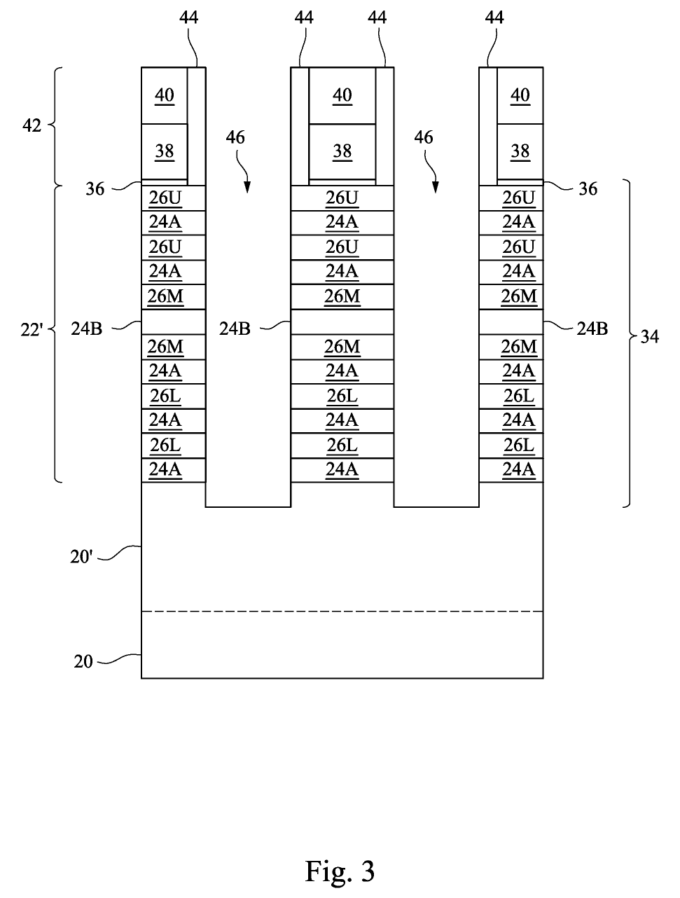

Reference is made to FIG. 3 to illustrate a schematic cross-sectional view of intermediate stages in the formation of CFETs in accordance with some embodiments. FIG. 3 illustrates the schematic cross-sectional view along the cross-section A-A’ in FIG. 1. FIG. 3 illustrates formation of source/drain recesses 46.

Next, the mask layer 40 is patterned using acceptable photolithography and etching techniques to form masks 40 as illustrated in FIG. 3. In FIG. 3, the pattern of the masks 40 is then transferred to the dummy gate layer 38 and to the dummy dielectric layer 36 to form dummy gates 38 and dummy dielectrics 36, respectively. The mask 40, the dummy gates 38 and the dummy dielectrics 36 are collectively referred to as dummy gate stacks 44. The dummy gates 38 cover respective channel regions of the nanostructures 24, 26. The pattern of the masks 40 may be used to physically separate each of the dummy gates 38 from adjacent dummy gates 38. The dummy gates 38 may also have a lengthwise direction substantially perpendicular to the lengthwise direction of respective fins 20’. The masks 40 can optionally be removed after patterning, such as by any acceptable etching technique.

In FIG. 3, gate spacers 44 are formed over the nanostructures 24, 26 and on exposed sidewalls of the masks 40 (if present), the dummy gates 38, and the dummy dielectrics 36. The gate spacers 44 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 38 (thus forming the gate spacers 44). Fin spacers may also be formed as part of forming the gate spacers 44.

Source/drain recesses 46 are formed in the nanostructures 24, 26, and the fins 20’. Epitaxial source/drain regions will be subsequently formed in the source/drain recesses 46. The source/drain recesses 46 may extend through the nanostructures 24, 26 and into the fins 20’. The fins 20’ may be etched such that bottom surfaces of the source/drain recesses 46 are disposed above, below, or level with the top surfaces of the isolation regions 32. The source/drain recesses 46 may be formed by etching the nanostructures 24, 26, and the substrate 50 using anisotropic etching processes, such as RIE, NBE, or the like. The gate spacers 44 and the dummy gates 38 mask portions of the nanostructures 24, 26, and the fins 20’ during the etching processes used to form the source/drain recesses 46. A single etch process or multiple etch processes may be used to etch each layer of the nanostructures 24, 26, and the fins 20’. Timed etch processes may be used to stop the etching of the source/drain recesses 46 after the source/drain recesses 46 reach a desired depth.

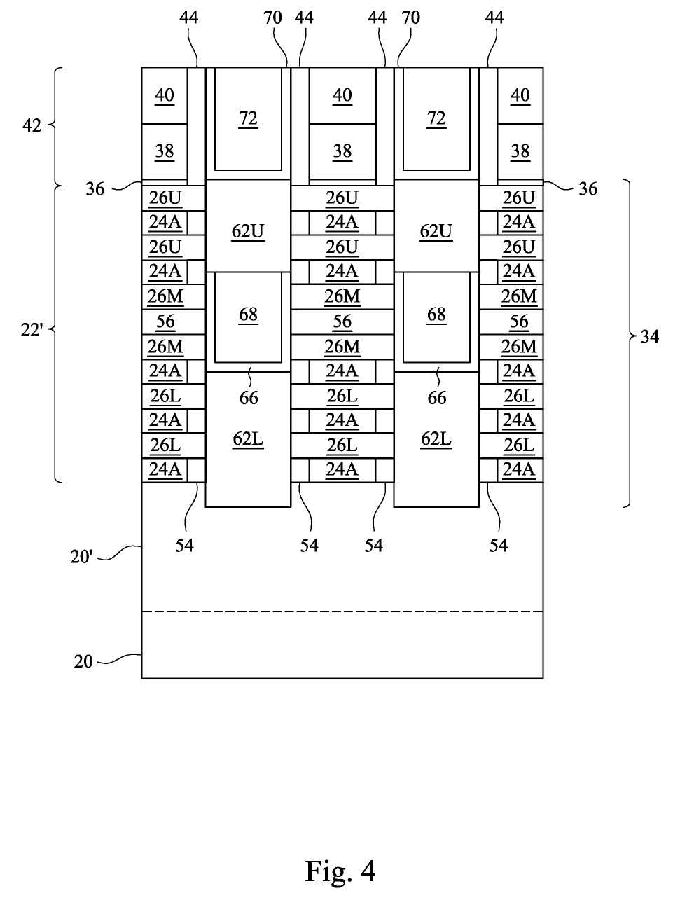

Reference is made to FIG. 4 to illustrate a schematic cross-sectional view of intermediate stages in the formation of CFETs in accordance with some embodiments. FIG. 4 illustrates the schematic cross-sectional view along the cross-section A-A’ in FIG. 1.

In FIG. 4, inner spacers 54 and dielectric isolation layers 56 are formed. Forming inner spacers 54 and dielectric isolation layers 56 (also referred to as isolation structures 56) may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the middle semiconductor nanostructures 26M without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 4), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the middle semiconductor nanostructures 26M. As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, the middle semiconductor nanostructures 26M and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24A, and between the middle semiconductor nanostructures 26M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 24A (thus forming the inner spacers 54) and has portions remaining in between the middle semiconductor nanostructures 26M (thus forming the dielectric isolation layers 56).

As also illustrated by FIG. 4, lower epitaxial source/drain regions 62L and upper epitaxial source/drain regions 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the nanostructures 24 and 26. In some embodiments, adjacent lower epitaxial source/drain regions 62L remain separated after the epitaxy process is completed. In other embodiments, these facets cause neighboring lower epitaxial source/drain regions 62L of the same FET to merge.

A first contact etch stop layer (CESL) 66 and a first interlayer dielectric (ILD) layer 68 are formed over the lower epitaxial source/drain regions 62L. The first CESL 66 may be formed of a dielectric material having a high etching selectivity from the etching of the first ILD layer 68, such as silicon nitride, silicon oxide, silicon oxynitride, or the like, which may be formed by any suitable deposition process, such as CVD, ALD, or the like. The first ILD layer 68 may be formed of a dielectric material, which may be deposited by any suitable method, such as CVD, plasma-enhanced CVD (PECVD), or FCVD. The applicable dielectric material of the first ILD layer 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD layer 68, followed by a planarization process and then an etch-back process. In some embodiments, the first ILD layer 68 is etched first, leaving the first CESL 66 unetched. An anisotropic etching process is then performed to remove the portions of the first CESL 66 higher than the recessed first ILD layer 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 62U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD layer 72 are formed. The materials and the formation methods may be similar to the materials and the formation methods of first CESL 66 and first ILD layer 68, respectively, and are not discussed in detail herein. The formation process may include depositing the layers for the second CESL 70 and the second ILD layer 72 and performing a planarization process to remove the excess portion of the corresponding layers. After the planarization process, top surfaces of the second ILD layer 72, the second CESL 70, the gate spacers 44, and the masks 40 are coplanar (within process variations). The planarization process may leave masks 40 unremoved (as shown), or may remove the masks 40, in which case the top surface of the second ILD layer 72 is level with the top surface of the dummy gate stacks 42.

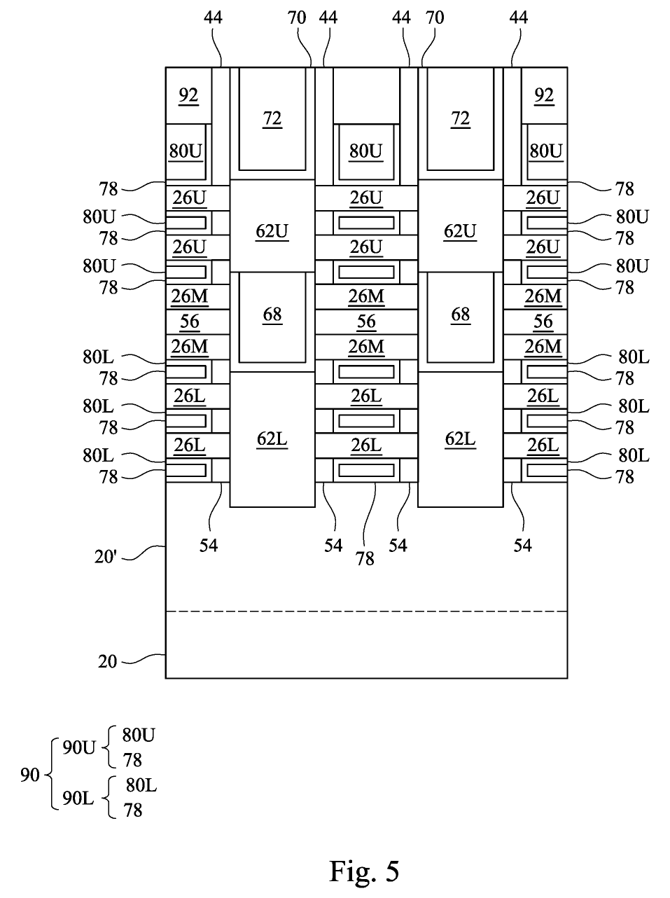

Reference is made to FIG. 5 to illustrate a schematic cross-sectional view of intermediate stages in the formation of CFETs in accordance with some embodiments. FIG. 5 illustrates the schematic cross-sectional view along the cross-section A-A’ in FIG. 1.

In FIG. 5, the mask 40 (if not removed already) is removed, e.g., by a CMP process. Next, the dummy gate stacks 42 are removed in one or more etching steps, so that recesses are formed between the gate spacers 44. In some embodiments, the dummy gates 38 and the dummy dielectrics 36 are removed by an anisotropic dry etch process. For example, the etching process may include a dry etch process using reaction gas(es) that selectively etch the material of the dummy gates 38. Each of the recesses formed between the gate spacers 44 exposes and/or overlies portions of nanostructures 24, 26 which act as the channel regions in the resulting devices. The portions of the nanostructures 24, 26 which act as the channel regions are disposed between neighboring pairs of the lower epitaxial source/drain regions 62L or between neighboring pairs of the upper epitaxial source/drain regions 62U. During the removal, the dummy dielectrics 36 may be used as etch stop layers when the dummy gates 38 are etched. The dummy dielectrics 36 may then be removed after the removal of the dummy gates 38.

The remaining portions of the first dummy nanostructures 24A are then removed to form openings in regions between the semiconductor nanostructures 26. The remaining portions of the first dummy nanostructures 24A can be removed by any acceptable etch process that selectively etches the material of the first dummy nanostructures 24A at a faster rate than the materials of the semiconductor nanostructures 26, the inner spacers 54, and the isolation structures 56. The etching may be isotropic. For example, when the first dummy nanostructures 24A are formed of silicon-germanium, the semiconductor nanostructures 26 are formed of silicon, the inner spacers 54 are formed of silicon oxycarbonitride, and the isolation structures 56 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 26 and expand the openings.

Next, a gate dielectric layer 78 is formed (e.g., conformally) over the nanostructures 26 including nanostructures 26L, 26M and 26U and along sidewalls of the isolation structures 56, such that the gate dielectric layer 78 conformally lines the recesses and the openings. Specifically, the gate dielectric layer 78 is formed on the top surfaces of the fins 20’; on the top surfaces, the sidewalls, and the bottom surfaces of the semiconductor nanostructures 26; along sidewalls of the isolation structures 56; and along the sidewalls of the gate spacers 44. The gate dielectric layer 78 wraps around all (e.g., four) sides of the semiconductor nanostructures 26. The gate dielectric layer 78 may also be formed on the top surfaces of the second ILD layer 72 and the gate spacers 44, and may be formed on the sidewalls of the fins 20’ (e.g., in embodiments where the top surfaces of the isolation regions 32 are below the top surfaces of the fins 20’).

The gate dielectric layer 78 may include an oxide such as silicon oxide or a metal oxide, a silicate such as a metal silicate, combinations thereof, multi-layers thereof, or the like. The gate dielectric layer 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 78 may include molecular-beam deposition (MBD), ALD, PECVD, and the like. A thickness of the gate dielectric layer 78 may be between about 1nm and about 5nm, as an example.

Next, as illustrated in FIG. 5, a gate fill material is formed in the recesses between the gate spacers 44 and the inner spacers 54. A planarization process, such as CMP, is performed to remove excess portions of this material from the upper surface of the second ILD layer 72 and the upper surfaces of the gate spacers 44. After planarization, the remaining material constitutes the gate electrodes 80, including both lower gate electrodes 80L and upper gate electrodes 80U. Specifically, portions of the gate fill material below the nanostructure 26M and between the nanostructures 26L and the fin 20’ are collectively referred to as the lower gate electrode 80L of the lower nanostructure-FET. Similarly, portions of the material above the nanostructure 26M and between the nanostructures 26U within the gate dielectrics 78 are collectively referred to as the upper gate electrode 80U of the upper nanostructure-FET.

The gate dielectrics 78 and the respective gate electrodes 80L and 80U are collectively referred to as gate stacks 90, which include upper gate stack 90U and lower gate stack 90L. In some embodiments, the resulting upper FET 10U and lower FET 10L share a common gate electrode 80.

In some embodiments, the gate fill material of the gate electrodes 80L and 80U is a metal-containing electrically conductive material such as tungsten, titanium, titanium nitride, tantalum, tantalum nitride, tantalum carbide, aluminum, ruthenium, cobalt, combinations thereof, multi-layers thereof, or the like. A suitable formation method, such as CVD, PVD, PECVD, or similar techniques, may be used to form the gate fill material of the gate electrodes 80L and 80U.

In some embodiments, the gate masks 92 are formed over the upper gate stack 90U. The formation process of the gate masks 92 may include recessing gate stacks 90, filling the resulting recesses with a dielectric material such as silicon nitride, silicon carbonitride, silicon oxynitride, silicon oxycarbonitride, or the like, and then performing a planarization process to remove the excess portions of the dielectric material over the second ILD layer 72.

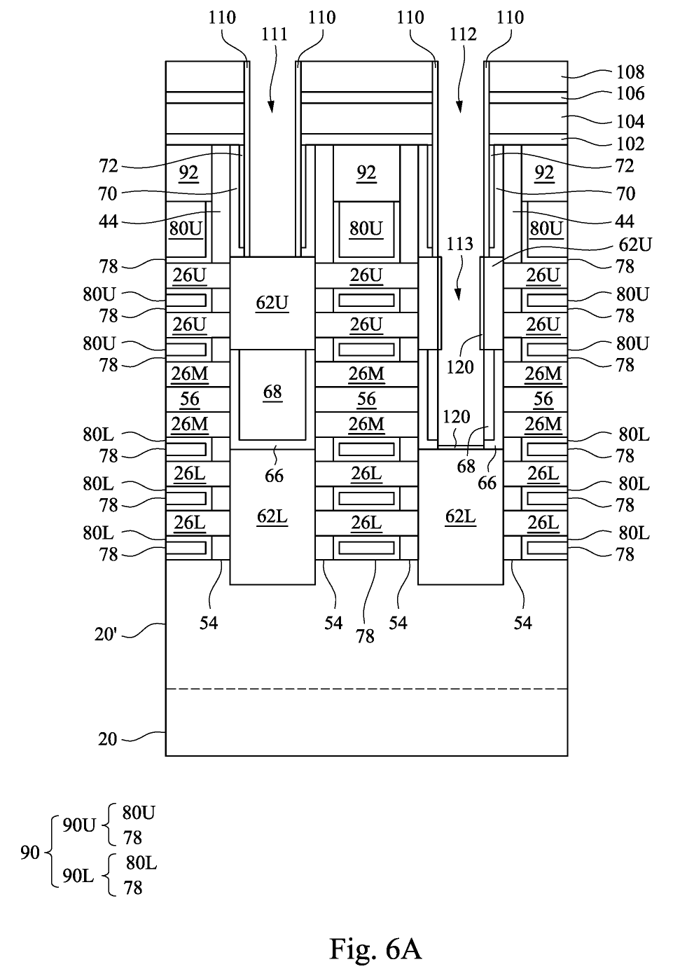

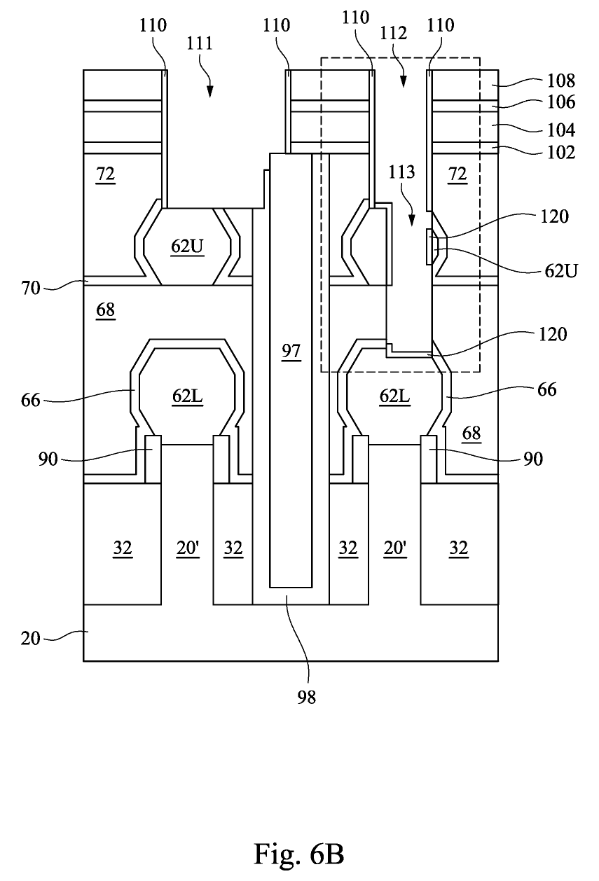

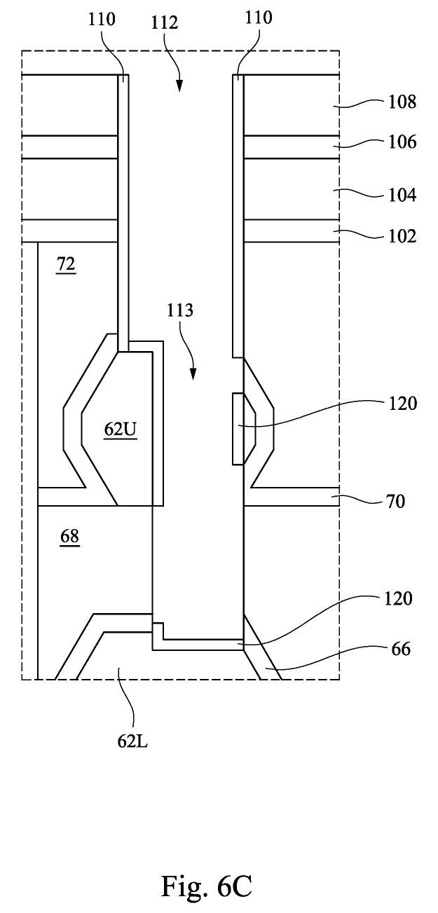

Reference is made to FIGS. 6A through 6C to illustrate cross-sectional views of intermediate stages in the formation of CFETs in accordance with some embodiments. FIG. 6A illustrates the schematic cross-sectional view along the cross-section A-A’ in FIG. 1. FIG. 6B illustrates the schematic cross-sectional view along the cross-section B-B’ in FIG. 1. FIG. 6C provides a detailed view of an area depicted in FIG. 6B.

In some embodiments, as illustrated in FIG. 6B, the CFET structure includes a vertical local interconnect (VLI) structure 97 between the adjacent lower nanostructure-FETs 10L and between the adjacent upper nanostructure-FETs 10U. The vertical local interconnect (VLI) structure 97 may be a vertical and diagonal local interconnect for connecting an epitaxial source/drain region 62U of one of the upper nanostructure-FETs 10U to an epitaxial source/drain region 62L of one of the lower nanostructure-FETs 10L out of the cross-sectional view of FIG. 6B. In FIG. 6B, the VLI structure 97 is laterally surrounded by a dielectric layer 98 between the adjacent lower nanostructure-FETs 10L and between the adjacent upper nanostructure-FETs 10U. In some embodiments, the VLI structure 97 and the dielectric layer 98 may be formed after the gate stacks 90 including the upper gate stacks 90U and the lower gate stacks 90L are formed by etching a trench in the CESLs 66, 70 and the ILD layers 68, 72 and forming the dielectric layer 98 and the VLI structure 97 in the trench.

In FIGS. 6A and 6B, an etch stop layer (ESL) 102 is formed over the gate masks 92, gate spacers 44, second CESL 70, and second ILD layer 72. An interlayer dielectric (ILD) layer 104 is formed over ESL 102, and an ESL 106 is formed over ILD layer 104, followed by ILD layer 108 over ESL 106. In some embodiments, the materials of ESLs 102 and 106 may be similar to those of ESLs 66 and 70, such as silicon nitride. Similarly, ILD layers 104 and 108 may be composed of materials similar to ILD layers 68 and 72, like silicon oxide. In some embodiments, the ESLs 102, 106 and the ILD layers 104, 108 can be formed using CVD, ALD, or other suitable techniques. In FIG. 6B, ESLs 102, 106, and ILD layers 104, 108 are positioned over VLI structure 97 and dielectric layer 98.

Openings 111 and 112 are formed through the ILD layers 104, 108, the ESL 102, 106, the second ILD layer 72 and the CESL 70. With respect to each of the openings 111 and 112, each of the openings 111 and 112 may be formed by performing an etching process, in which the etching process may stop until the top surface of the corresponding upper epitaxial source/drain regions 62U is exposed. In some embodiments, the openings 111 and 112 may be formed through different photolithography processes. For example, the opening 111 may be formed prior to or after the opening 112. Additionally, as illustrated in FIG. 6B, the dielectric layer 98 is etched, revealing a top surface and a sidewall of the VLI structure 97 from opening 111.

Next, as illustrated in FIGS. 6A through 6C, liner insulating layers 110 are formed on the inner sidewalls of the openings 111 and 112 and exposed surfaces of the upper epitaxial source/drain regions 62U. In some embodiments, the liner insulating layers 110 are made of a silicon nitride-based material, such as SiN. The liner insulating layers 110 are formed by LPCVD, plasma-CVD, ALD or any other suitable film formation methods. The liner insulating layers 110 formed on the exposed surfaces of the upper epitaxial source/drain regions 62U are removed by etching to expose the upper epitaxial source/drain regions 62U. In some embodiments, portions of the upper epitaxial source/drain regions 62U are recessed (etched) after being exposed from the liner insulating layers 110.

After the liner insulating layers 110 are formed, in one or more embodiments of the present disclosure, an opening 113 is formed. With respect to the opening 113, the opening 113 may be formed by performing a suitable etching process, in which the etching process stops until the top surface of the corresponding lower epitaxial source/drain region 62L is exposed. In the cross-sectional view of FIGS. 6A and 6B, the opening 113 may penetrate through the corresponding upper epitaxial source/drain regions 62U and expose the top surface of the corresponding lower epitaxial source/drain region 62L. In some embodiments, the etching process may also slightly etch the corresponding lower epitaxial source/drain region 62L, such that the bottom end of the opening 113 may extend into the corresponding lower epitaxial source/drain region 62L. In some embodiments, the openings 112 and 113 are collectively referred to as a Metal Over Diffusion Local Interconnect (MDLI) opening, which extends from one of the upper epitaxial source/drain regions 62U to the corresponding lower epitaxial source/drain region 62L.

In some embodiments, patterned masks are formed in openings 111 and 112 prior to form opening 113. The patterned mask temporarily fills opening 111, preventing additional openings therein. In the opening 112, the patterned mask partially fills the space, allowing opening 113 to be formed from the bottom and have a width less than a width of opening 112. The patterned masks in openings 111 and 112 are removed after forming the opening 113.

As illustrated in FIGS. 6A through 6C, after forming the opening 113, exposed surfaces of the upper epitaxial source/drain region 62U and the lower epitaxial source/drain region 62L are natively oxidized due to exposure to ambient, forming native oxide layers 120 on the upper epitaxial source/drain region 62U and the lower epitaxial source/drain region 62L. In some embodiments, the native oxide layers 120 include silicon oxide.

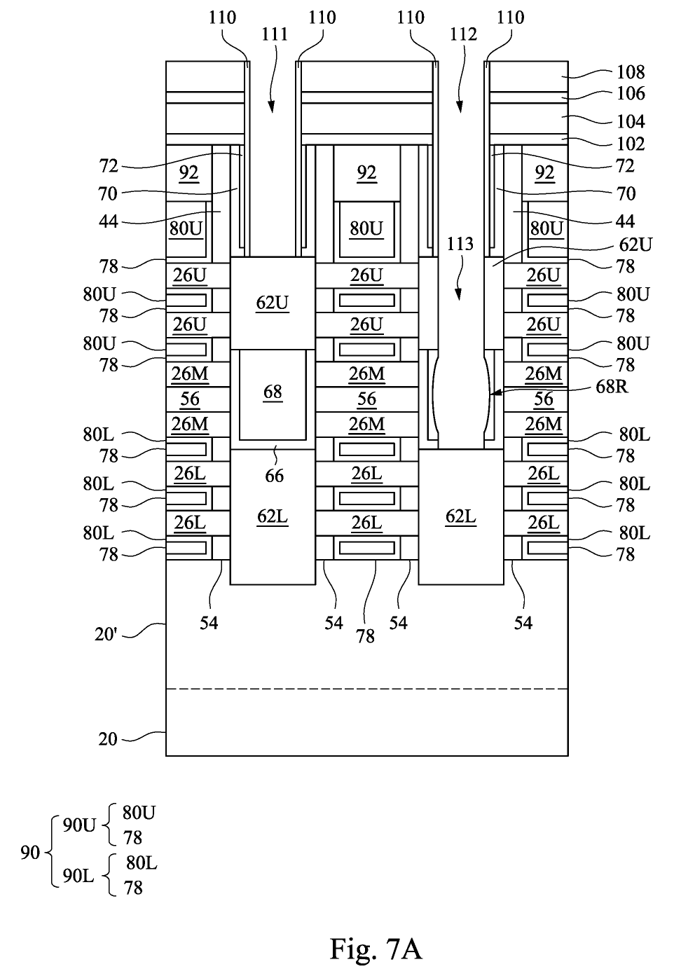

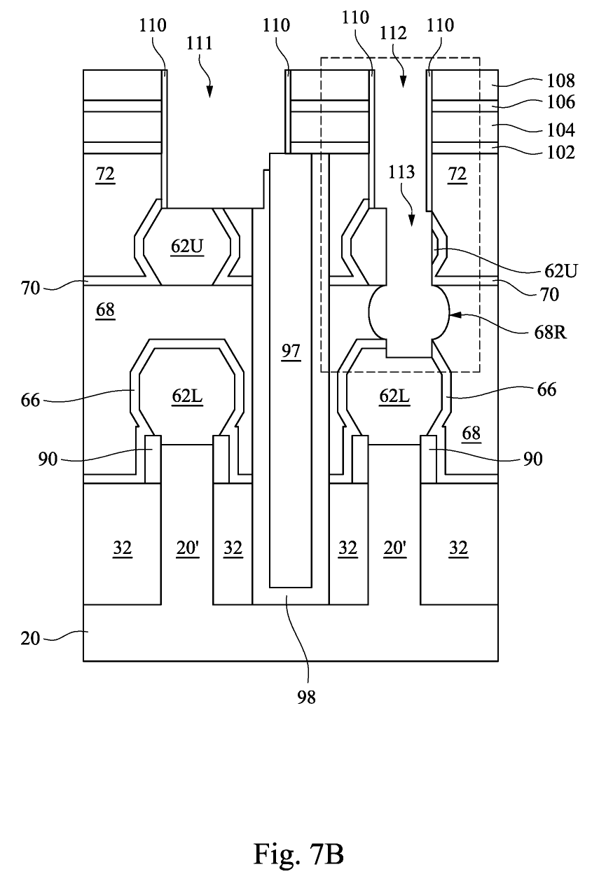

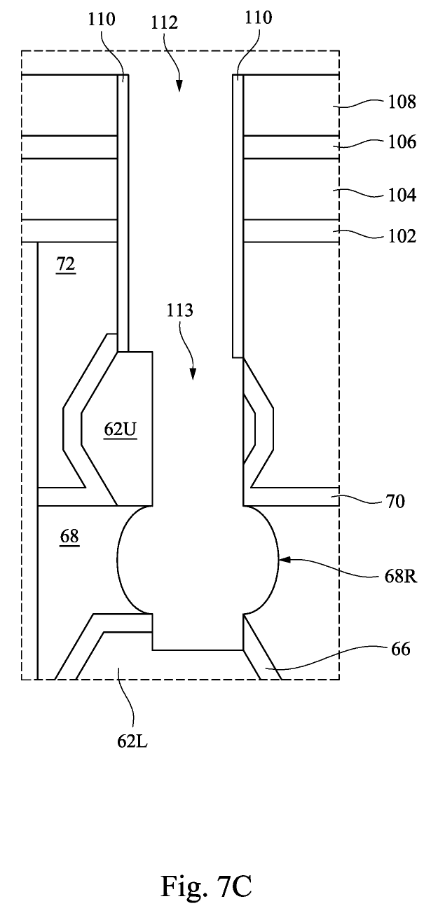

Reference is made to FIGS. 7A through 7C to illustrate cross-sectional views of intermediate stages in the formation of CFETs in accordance with some embodiments. FIG. 7A illustrates the schematic cross-sectional view along the cross-section A-A’ in FIG. 1. FIG. 7B illustrates the schematic cross-sectional view along the cross-section B-B’ in FIG. 1. FIG. 7C illustrates a zoom-in view of FIG. 7B.

FIGS. 7A through 7C illustrate performing a pre-clean process for formation of silicide layers, wherein the pre-clean process is performed to remove the native oxide layers 120 formed on the exposed surfaces of the upper epitaxial source/drain region 62U and the lower epitaxial source/drain region 62L. In some embodiments, removal of the native oxide layer 120 over the upper epitaxial source/drain region 62U and the lower epitaxial source/drain region 62L includes an isotropic etching process. The ILD layers 68 and 72 may include oxide material. The liner insulating layers 110 covers and protects the ILD layer 72 from damage by the removal of the pre-clean process. In one or more embodiments of the present disclosure, the removal of the native oxide layers 120 laterally recess sidewalls of the ILD layer 68. As illustrated in FIGS. 7A through 7C, lateral recesses 68R are formed over the sidewalls of the ILD layer 68.

Metal gap-fill material may be sequentially formed in the openings 111, 112 and 113. In some embodiments, voids may appear in the following metal gap-fill material formed in the opening 113 because of the lateral recesses 68R on the sidewalls of the ILD layer 68, causing high resistance and reliability issue. In one or more embodiments of the present disclosure, the lateral recesses 68R on the sidewalls of the ILD layer 68 in the opening 113 are refilled, and it allows the voids within the metal gap-fill material in the opening 113 to shrink or even disappear.

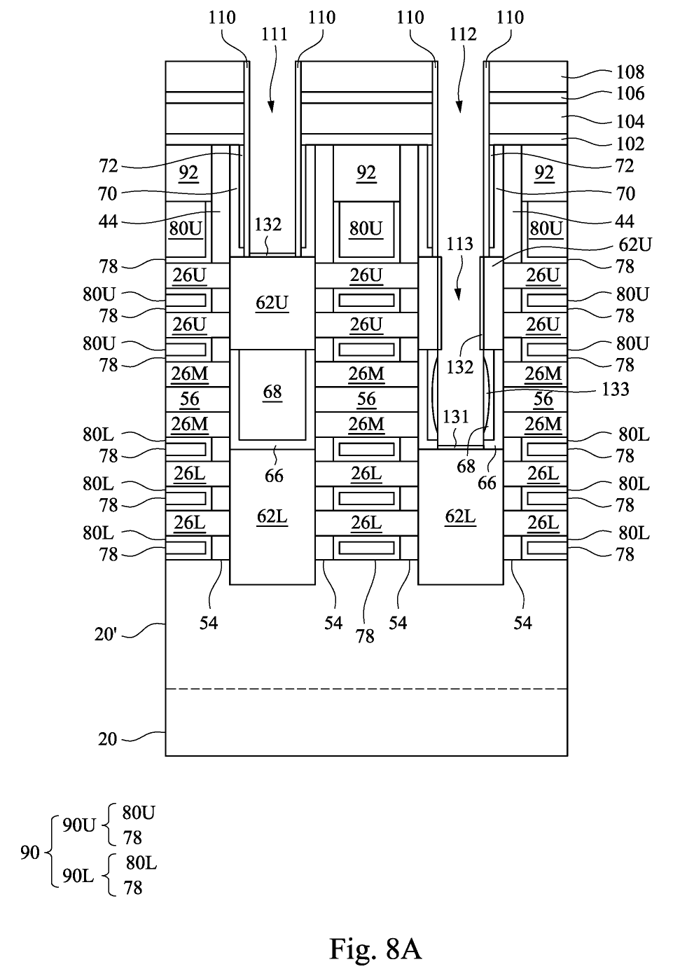

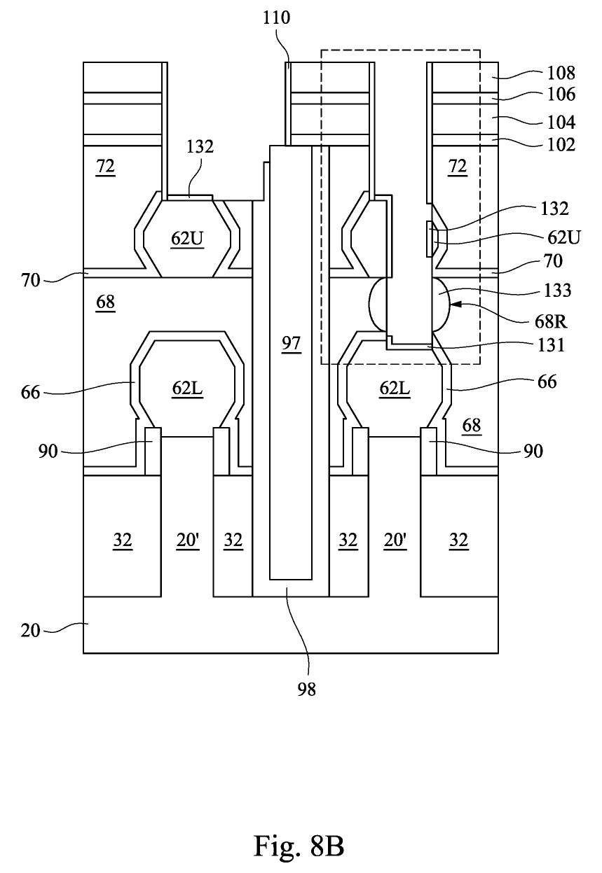

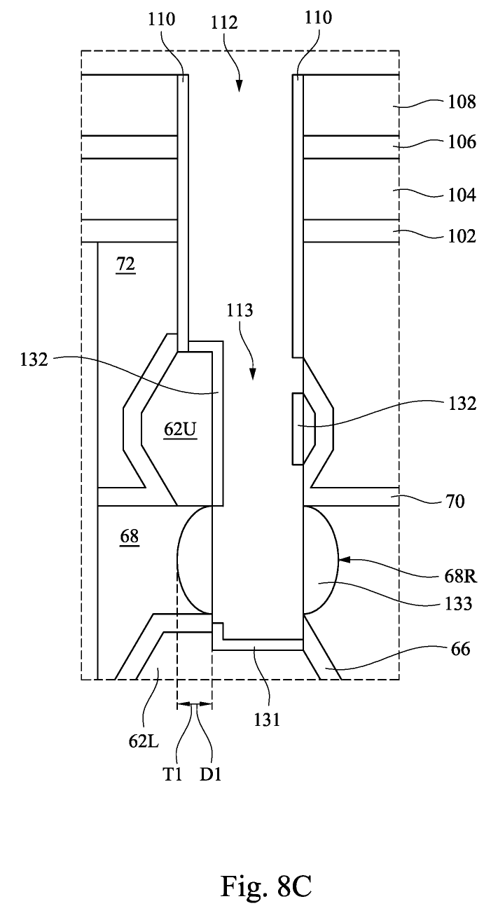

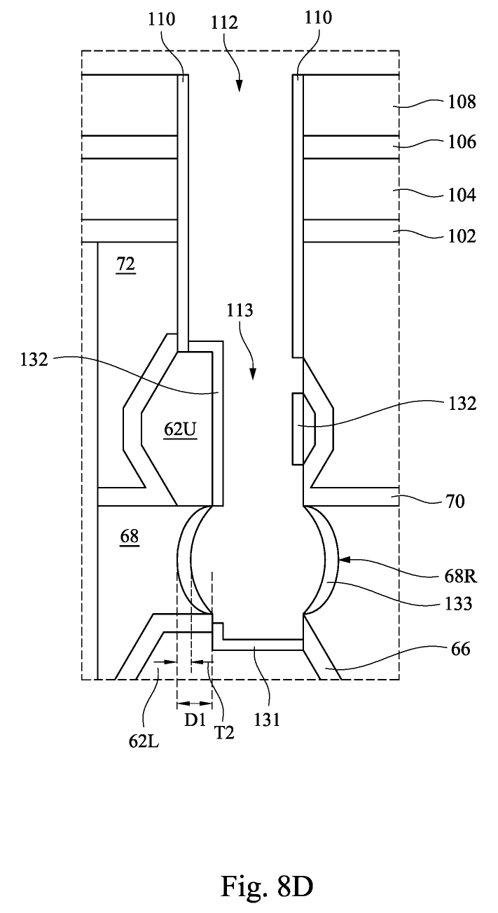

Reference is made to FIGS. 8A through 8D to illustrate cross-sectional views of intermediate stages in the formation of CFETs in accordance with some embodiments. FIG. 8A illustrates the schematic cross-sectional view along the cross-section A-A’ in FIG. 1. FIG. 8B illustrates the schematic cross-sectional view along the cross-section B-B’ in FIG. 1. FIGS. 8C and 8D illustrate zoom-in views of FIG. 8B in accordance with some embodiments.

FIGS. 8A through 8C illustrate formation of silicide layers 131 over the lower epitaxial source/drain region 62L and silicide layers 132 over the upper epitaxial source/drain region 62U.

Formation of the silicide layers 131 and 132 include forming metal-containing material in the openings 111, 112 and 113. In order to refill the recesses 68R in the opening 113, the metal-containing material has growth selectivity on different material surface. For example, the metal-containing material for forming the silicide layers 131, 132 and refilling the recesses 68R can include titanium nitride (TiN) or zirconium chloride (ZrClₓ). The metal-containing material is formed in the openings 111, 112 and 113 by a suitable deposition process with deposition selectivity on different material surface, and a deposition rate (i.e., growth rate) of the metal-containing material on the lower epitaxial source/drain region 62L and the upper epitaxial source/drain region 62U is greater than a deposition rate of the metal-containing material on the liner insulating layers 110 and is less than a deposition rate of the metal-containing material on the ILD layer 68. The metal-containing material has a lower deposition rate on the surfaces of the liner insulating layers 110, such that no thickness or negligible thickness of silicide layer will be formed on the surfaces of the liner insulating layers 110. Accordingly, after the silicide layers 131, 132 and the metal-containing layer 133 are formed, majority of the surfaces of the liner insulating layers 110 are exposed.

As illustrated in FIGS. 8A through 8C, the silicide layer 131 is formed by the metal-containing material on the lower epitaxial source/drain region 62L. The silicide layer 132 is formed by the metal-containing material on the upper epitaxial source/drain regions 62U. The metal-containing layers 133 are formed and refilled with the recesses on the ILD layer 68. The metal-containing layers 133 are embedded in the ILD layer 68. The silicide layers 131 and 132 include silicide material of the metal-containing layers 133. For example, the metal-containing layers 133 are TiN layers, and the silicide layers 131 and 132 are titanium silicide nitride (TiSiN) layer. For example, the metal-containing layers 133 are ZrClₓ layers, and the silicide layers 131 and 132 are zirconium silicide layer.

FIG. 8C illustrates the metal-containing layers 133 in the recesses 68R have nearly flat surfaces. A thickness of each of the metal-containing layers 133 decreases from the center to the outer edges. A maximum thickness T1 of each of the metal-containing layers 133 can be a lateral depth D1 of each of the recesses 68R from the sidewalls of the ILD layer 68. In some embodiments, the maximum thickness T1 of each of the metal-containing layers 133 is in a range from about several angstroms to about 12nm.

It is noted that the metal-containing layers 133 cannot protrude beyond the sidewalls of the ILD layer 68. If the metal-containing layers 133 extend beyond the sidewalls of the ILD layer 68, it will affect the subsequent growth of the metal gap-fill material. In other words, the maximum thickness T1 of the metal-containing layers 133 is equal to or less than the lateral depth D1 of the recesses 68R. FIG. 8D illustrates a zoom-in view of FIG. 8B in accordance with some embodiments. As illustrated in FIGS. 8C and 8D, the structure in FIG. 8D may be substantially the same as the structure in FIG. 8C, except that the metal-containing layers 133 in the recesses 68R has recess surfaces. In FIG. 8D, the maximum thickness T1 of each of the metal-containing layers 133 is less than the lateral depth D1 of each of the recesses 68R from the sidewalls of the ILD layer 68.

As illustrated in FIG. 8A, the silicide layers 131 and 132 are formed over the exposed surfaces of the lower epitaxial source/drain region 62L and silicide layers 132 over the upper epitaxial source/drain region 62U. In some embodiments, the metal-containing material for forming the silicide layers 131 and 132 can be formed over the VLI structure 97 exposed from the opening 111 and referred to as a portion of the VLI structure 97.

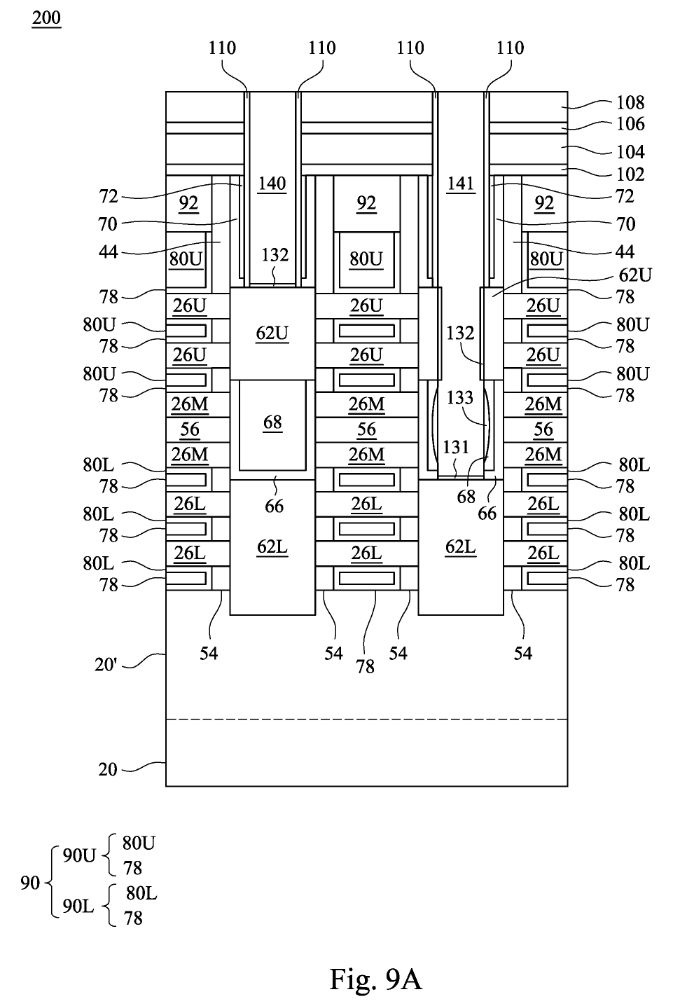

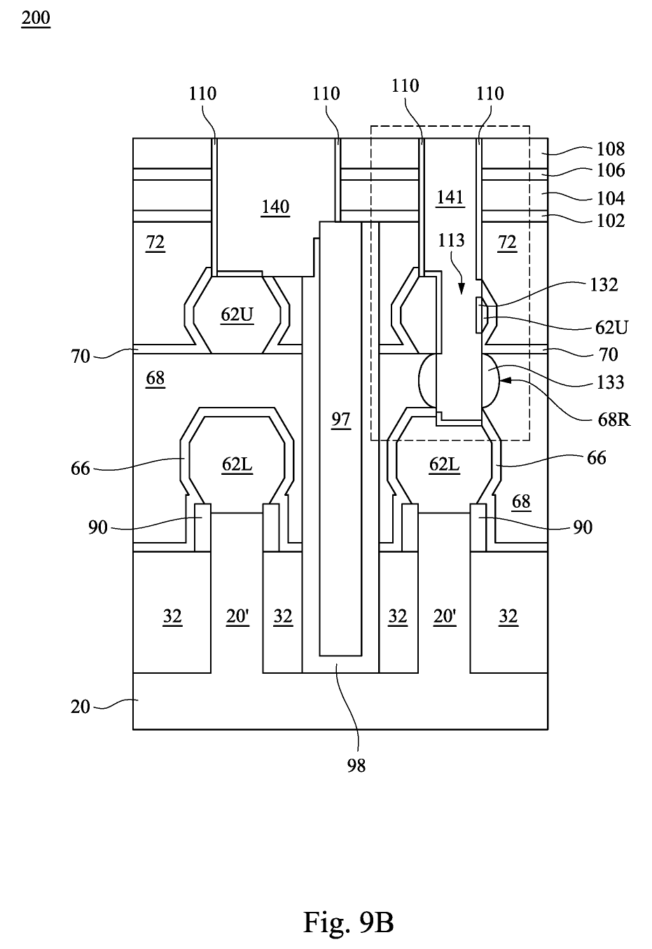

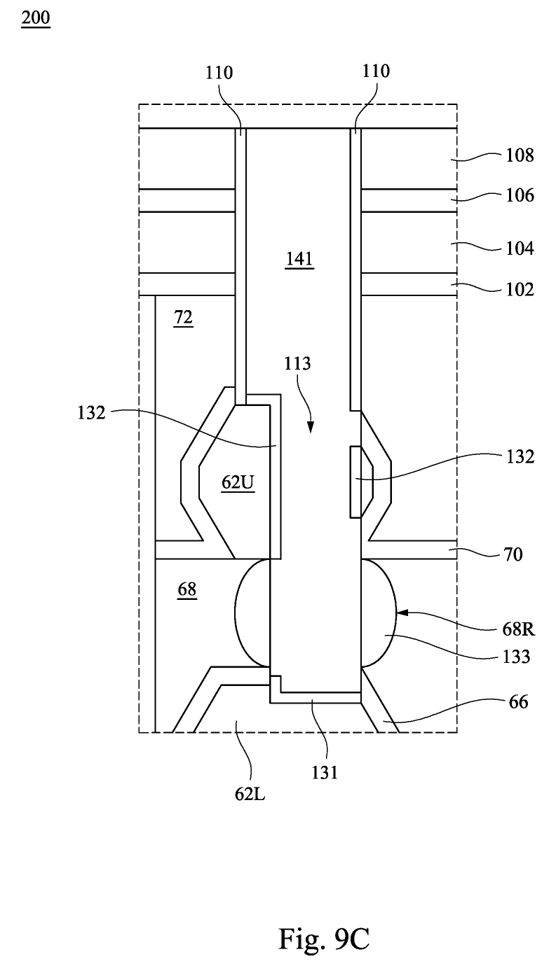

Reference is made to FIGS. 9A through 9C to illustrate cross-sectional views of intermediate stages in the formation of CFETs in accordance with some embodiments. FIG. 9A illustrates the schematic cross-sectional view along the cross-section A-A’ in FIG. 1. FIG. 9B illustrates the schematic cross-sectional view along the cross-section B-B’ in FIG. 1. FIG. 9C illustrates a zoom-in view of FIG. 9B.

FIGS. 9A through 9C illustrate formation of a metal gap-fill material in the openings 111, 112 and 113 to form metal plugs 141 and 142. The metal plugs 141 are formed in the openings 111. The metal plug 142 is formed in the MDLI opening including the openings 112 and 113. The metal plugs 141 and 142 may be formed using suitable deposition process, such as CVD, atomic layer deposition (ALD), or the like. In some embodiments, the materials of the metal plugs 141 and 142 may include tungsten (W), copper (Cu), aluminum (Al), ruthenium (Ru), cobalt (Co), molybdenum (Mo), nickel (Ni), or other suitable conductive material. In some embodiments, a planarization process (such as CMP) is performed to remove excess portions of metal gap-fill material out of the openings 111, 112 and 113.

As illustrated in FIGS. 9A through 9C, a semiconductor structure 200 is formed. The semiconductor structure 200 is a CFET device and includes lower nanostructure-FETs and upper nanostructure-FETs. The semiconductor structure 200 includes the metal plug 142, wherein the metal plug 142 can be referred to as a MDLI interconnecting one of the upper epitaxial source/drain regions 62U of one of the lower nanostructure-FETs and the corresponding lower epitaxial source/drain region 62L of one of the upper nanostructure-FETs. In FIGS. 9B and 9C, the metal-containing layers 132 of a metal-containing material for forming the silicide layers 131 and 132 are filled with the recesses 68R on the sidewalls of the ILD layer 68, which is over the lower epitaxial source/drain region 62L. Each of the metal-containing layers 132 is between the metal plug 142 and the corresponding sidewall of the ILD layer 68. In some embodiments, the material of the metal-containing layers 132 is different from the material of the metal plug 142.

According to one or more embodiments of the present disclosure, a method includes a number of operations. A bottom transistor is formed over a substrate. A top transistor is formed over the top transistor. An opening is formed and extends through a source/drain region of the top transistor to a source/drain region of the bottom transistor, wherein the opening further extends through an interlayer dielectric (ILD) layer between the source/drain regions of the top and bottom transistors. A metal-containing material is formed over the source/drain regions of the top and bottom transistors to form silicide layers over the source/drain regions of the top and bottom transistors, wherein recesses in sidewalls of the ILD layer are filled with the metal-containing material. After forming the metal-containing material, a metal gap-fill material is formed in the opening. In one or more embodiments of the present disclosure, the metal-containing material is different from the metal gap-fill material. In one or more embodiments of the present disclosure, a growth rate of the metal-containing material over the ILD layer is greater than a growth rate of the metal-containing material over the source/drain regions of the top and bottom transistors. In one or more embodiments of the present disclosure, the metal-containing material comprises titanium nitride or zirconium chloride. In one or more embodiments of the present disclosure, the metal-containing material in the recesses of the ILD layer has a thickness decreasing from a center to opposite edges of the metal-containing material. In one or more embodiments of the present disclosure, the metal-containing material in the recesses of the ILD layer has a recessed profile.

According to one or more embodiments of the present disclosure, a method includes a number of operations. A bottom transistor is formed over a substrate. A first interlayer dielectric (ILD) layer is formed over the bottom transistor. A top transistor is formed over the first ILD layer. A second ILD layer is formed over the top transistor. A first opening is formed and extends through the second ILD layer and to a top surface of a source/drain region of the top transistor. A liner insulating film is formed over sidewalls of the first opening and exposing the top surface of the source/drain region of the top transistor. A second opening is formed and extends through the source/drain region of the top transistor and the first ILD layer to a top surface of a source/drain region of the bottom transistor. After forming the second opening, oxides are removed from the source/drain regions of the top and bottom transistors. A metal-containing material is formed in the first and second opening, wherein a growth rate of the metal-containing material on the first ILD layer is greater than a growth rate of the metal-containing material on the source/drain regions of the top and bottom transistors. After forming the metal-containing material, a metal gap-fill material is formed in the first and second openings. In one or more embodiments of the present disclosure, recesses are formed on sidewalls of the first ILD layer during removing the oxides from the source/drain regions of the top and bottom transistors. Forming the metal-containing material includes filling the metal-containing material in the recess of the ILD layer. In some embodiments, the metal-containing material in the recesses of the ILD layer has a recessed profile. In some embodiments, the metal-containing material in the recesses of the ILD layer has a thickness decreasing from a center to opposite edges of the metal-containing material. In some embodiments, a width of the first opening is greater than a width of the second opening. In one or more embodiments of the present disclosure, a growth rate of the metal-containing material on the source/drain regions of the top and bottom transistors is greater than a growth rate of the metal-containing material on the liner insulating film. In one or more embodiments of the present disclosure, the metal-containing material is different from the metal gap-fill material. In one or more embodiments of the present disclosure, the metal-containing material comprises titanium nitride or zirconium chloride.

According to one or more embodiments of the present disclosure, a semiconductor structure includes a bottom transistor, a first interlayer dielectric (ILD) layer, a top transistor, a metal-containing layer and a metal plug. The bottom transistor is over a substrate. The first ILD layer is over the bottom transistor. The top transistor is over the first ILD layer. The metal-containing layer is embedded in a sidewall of the first ILD layer between source/drain regions of the top and bottom transistors. The metal plug extends through the source/drain region of the top transistor and the first ILD layer to the source/drain region of the bottom transistor. The metal-containing layer is between the metal plug and the first ILD layer. In one or more embodiments of the present disclosure, the semiconductor structure further includes a second ILD layer and a lining insulating film. The second ILD layer is over the top transistor. The lining insulating film is over a sidewall of the second ILD layer. The metal plug extends from a top surface of the second ILD layer. The lining insulating film is between the metal plug and the second ILD layer. In one or more embodiments of the present disclosure, the lining insulating film comprises silicon nitride. In one or more embodiments of the present disclosure, the metal-containing layer in the recesses of the ILD layer has a thickness decreasing from a center to opposite edges of the metal-containing layer. In one or more embodiments of the present disclosure, a material of the metal-containing layer is different from a material of the metal plug. In one or more embodiments of the present disclosure, a material of the metal-containing layer comprises titanium nitride or zirconium chloride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a bottom transistor over a substrate;
forming a top transistor over the top transistor;
forming an opening extending through a source/drain region of the top transistor to a source/drain region of the bottom transistor, the opening further extending through an interlayer dielectric (ILD) layer between the source/drain regions of the top and bottom transistors;
forming a metal-containing material over the source/drain regions of the top and bottom transistors to form silicide layers over the source/drain regions of the top and bottom transistors, wherein recesses in sidewalls of the ILD layer are filled with the metal-containing material; and
after forming the metal-containing material, forming a metal gap-fill material in the opening.

2. The method of claim 1, wherein the metal-containing material is different from the metal gap-fill material.

3. The method of claim 1, wherein a growth rate of the metal-containing material over the ILD layer is greater than a growth rate of the metal-containing material over the source/drain regions of the top and bottom transistors.

4. The method of claim 1, wherein the metal-containing material comprises titanium nitride or zirconium chloride.

5. The method of claim 1, wherein the metal-containing material in the recesses of the ILD layer has a thickness decreasing from a center to opposite edges of the metal-containing material.

6. The method of claim 1, wherein the metal-containing material in the recesses of the ILD layer has a recessed profile.

7. A method, comprising:
forming a bottom transistor over a substrate;
forming a first interlayer dielectric (ILD) layer over the bottom transistor;
forming a top transistor over the first ILD layer;
forming a second ILD layer over the top transistor;
forming a first opening extending through the second ILD layer and to a top surface of a source/drain region of the top transistor;
forming a liner insulating film over sidewalls of the first opening and exposing the top surface of the source/drain region of the top transistor;
forming a second opening extending through the source/drain region of the top transistor and the first ILD layer to a top surface of a source/drain region of the bottom transistor;
after forming the second opening, removing oxides from the source/drain regions of the top and bottom transistors;
forming a metal-containing material in the first and second opening, wherein a growth rate of the metal-containing material on the first ILD layer is greater than a growth rate of the metal-containing material on the source/drain regions of the top and bottom transistors; and
after forming the metal-containing material, forming a metal gap-fill material in the first and second openings.

8. The method of claim 7, wherein recesses are formed on sidewalls of the first ILD layer during removing the oxides from the source/drain regions of the top and bottom transistors, forming the metal-containing material comprises:
filling the metal-containing material in the recess of the ILD layer.

9. The method of claim 8, wherein the metal-containing material in the recesses of the ILD layer has a recessed profile.

10. The method of claim 8, wherein the metal-containing material in the recesses of the ILD layer has a thickness decreasing from a center to opposite edges of the metal-containing material.

11. The method of claim 7, wherein a width of the first opening is greater than a width of the second opening.

12. The method of claim 7, wherein a growth rate of the metal-containing material on the source/drain regions of the top and bottom transistors is greater than a growth rate of the metal-containing material on the liner insulating film.

13. The method of claim 7, wherein the metal-containing material is different from the metal gap-fill material.

14. The method of claim 7, wherein the metal-containing material comprises titanium nitride or zirconium chloride.

15. A semiconductor structure, comprising:
a bottom transistor over a substrate;
a first interlayer dielectric (ILD) layer over the bottom transistor;
a top transistor over the first ILD layer;
a metal-containing layer embedded in a sidewall of the first ILD layer between source/drain regions of the top and bottom transistors; and
a metal plug extending through the source/drain region of the top transistor and the first ILD layer to the source/drain region of the bottom transistor, wherein the metal-containing layer is between the metal plug and the first ILD layer.

16. The semiconductor structure of claim 15, further comprising:
a second ILD layer over the top transistor;
a lining insulating film over a sidewall of the second ILD layer, wherein the metal plug extends from a top surface of the second ILD layer, and the lining insulating film is between the metal plug and the second ILD layer.

17. The semiconductor structure of claim 16, wherein the lining insulating film comprises silicon nitride.

18. The semiconductor structure of claim 15, wherein the metal-containing layer in recesses of the ILD layer has a thickness decreasing from a center to opposite edges of the metal-containing layer.

19. The semiconductor structure of claim 15, wherein a material of the metal-containing layer is different from a material of the metal plug.

20. The semiconductor structure of claim 15, wherein a material of the metal-containing layer comprises titanium nitride or zirconium chloride.
